(19) United States
(12) Patent Application Publication
(10) Pub. No.: US 2023/0361063 A1
(43) Pub. Date: Nov. 9, 2023

(54) Semiconductor Integrated Circuit

(71) Applicant: Nippon Telegraph and Telephone Corporation, Tokyo (JP)

(72) Inventors: Miwa Muto, Musashino-shi, Tokyo (JP); Hideaki Matsuzaki, Musashino-shi, Tokyo (JP)

(21) Appl. No.: 18/245,404

(22) PCT Filed: Sep. 23, 2020
(86) PCT No.: PCT/JP2020/035710

§ 371 Date: Mar. 15, 2023

(51) Int. Cl. H01L 23/00

(52) U.S. Cl. CPC H01L 24/05; H01L 2224/05556; H01L 2224/02206

(57) ABSTRACT

A second protective film is formed on and in contact with a first protective film, and is formed to cover the first protective film. The second protective film is also formed so that an end portion extending toward the center of a first opening is interposed between a wiring line and a bonding pad at the edge portion of the bonding pad.

### TECHNICAL FIELD

The present invention relates to a semiconductor integrated circuit including bonding pads.

### BACKGROUND ART

For an insulating film to be used in an integrated circuit that operates at a high speed using a compound semiconductor, an organic insulating film such as a polyimide or benzocyclobutene (BCB) film having a low dielectric constant is often used so as to reduce wiring delays. However, compared with an inorganic insulating film such as a silicon oxide film or a silicon nitride film, an organic insulating film is higher in moisture absorbency and water permeability, and it is difficult to achieve a high moisture resistance with an organic insulating film. For this reason, in an integrated circuit using an organic insulating film, expensive hermetically sealed packaging such as ceramic packaging is often used, which has greatly hindered cost reduction.

In recent years, on the other hand, there has been an increasing demand for cost reduction in an ultra-high-speed integrated circuit using a compound semiconductor, and the use of inexpensive plastic packaging is becoming a goal to achieve. In a case where plastic packaging is used, airtightness cannot be ensured by packaging, and therefore, it is necessary to secure moisture resistance with an integrated circuit chip.

In a case where an insulating film formed with an organic material is used, to ensure moisture resistance, a configuration in which portions other than the bonding pad portions are covered with an insulating protective film formed with an inorganic material such as silicon nitride that hardly passes water is normally used. This example configuration is now described with reference to FIG. 3. First, bonding pads 202 are formed on edge portions of an integrated circuit formed with a semiconductor. An organic insulating protective film 203 formed with an organic material is formed on a substrate 201, and an inorganic insulating protective film 204 formed with an inorganic material is formed on the organic insulating protective film 203. The bonding pads 202 are connected to a circuit element formation region (not illustrated) by metal wiring lines 211.

Further, in the bonding regions 212 of the bonding pads 202, the organic insulating protective film 203 and the inorganic insulating protective film 204 have openings, and the surfaces of the bonding pads 202 are exposed. In this example, the organic insulating protective film 203 is formed in contact with the edge portions of the bonding pads 202 so as to cover the edge portions of the bonding pads 202. Also, the inorganic insulating protective film 204 covers the organic insulating protective film 203, and is formed in contact with the edge portions of the bonding pads 202. The organic insulating protective film 203 formed with an organic material is formed on and in contact with the metal wiring lines 211. Note that the bonding pads 202 need to be connected to an external circuit by wire bonding, and therefore, the bonding pads 202 are formed with a metal such as gold (Au), which is hardly oxidized.

Further, to improve the adhesion between the bonding pads and the protective films, there is a suggested technique by which an adhesion enhancing film formed with a metal material containing titanium is inserted between bonding pads formed with Au having poor adhesiveness and an inorganic insulating film so that the bonding pads do not come into direct contact with the inorganic insulating film (see Patent Literature 1).

### CITATION LIST

### Patent Literature

Patent Literature 1: JP 2018-206896 A

### SUMMARY OF INVENTION

### Technical Problem

In the integrated circuit described above, the bonding pads are often formed with Au like the wiring lines, but it is widely known that high adhesiveness is hardly obtained between an inorganic material such as silicon nitride and Au. If sufficiently high adhesiveness cannot be obtained between the bonding pads and the inorganic insulating protective film, moisture penetrates from a portion where adhesiveness is not sufficiently high. In the example illustrated in FIG. 3, a path indicated by a bold line between a bonding pad 202 and the inorganic insulating protective film 204 is a penetration path of moisture reaching the organic insulating protective film 203. Once moisture penetrates the inside of the inorganic insulating protective film, the moisture easily reaches the circuit element formation region, because the organic insulating film inside has a high water permeability. As a result, sufficiently high moisture resistance cannot be ensured.

Also, by the technique involving insertion of an adhesion enhancing film, the adhesion between the adhesion enhancing film and the inorganic insulating film, and the adhesion between the adhesion enhancing film and the bonding pads are not sufficiently high, and therefore, there is a possibility of moisture penetration.

To counter the above problem, the area in which the bonding pads and the protective film are in contact with each other may be made larger so as to make the moisture penetration path longer and enhance the moisture resistance. However, increasing the area of contact will lead to smaller bonding regions for the bonding pads. To secure wide bonding regions, the areas of the bonding pads are made larger, which will increase the area of the semiconductor integrated circuit.

The present invention has been made to solve the above problems, and aims to prevent reduction of bonding regions so as to prevent penetration of moisture in bonding pads.

### Solution to Problem

A semiconductor integrated circuit according to the present invention includes: a substrate that is formed with a semiconductor; a circuit element formation region that is formed on the substrate, and includes an element formed with a semiconductor; a wiring line that is drawn from the circuit element formation region onto the substrate in a pad formation region around the circuit element formation region; a first protective film that covers the circuit element formation region, has a first opening formed in the pad formation region, and is formed with an organic material; a bonding pad that has a smaller area than the first opening in a planar view, is formed on the wiring line on the inner side of the first opening, and is connected to the wiring line; and a second protective film that is in contact with the first protective film to cover the first protective film, has an end portion extending toward the center of the first opening between the wiring line and the bonding pad at an edge portion of the bonding pad, has a second opening that is formed on the inner side of the first opening and has the end portion as an edge, and is formed with an inorganic material.

### Advantageous Effects of Invention

As described above, according to the present invention, an end portion of the second protective film formed to cover a first protective film is inserted between a wiring line and a bonding pad. Thus, it is possible to prevent a reduction of the bonding region, and prevent penetration of moisture into the bonding pad.

### BRIEF DESCRIPTION OF DRAWINGS

FIG. 1A is a cross-sectional view illustrating a partial configuration of a semiconductor integrated circuit according to an embodiment of the present invention.

FIG. 1B is a plan view illustrating a partial configuration of a semiconductor integrated circuit according to an embodiment of the present invention.

FIG. 1C is a plan view illustrating the configuration of a semiconductor integrated circuit according to an embodiment of the present invention.

FIG. 2 is a cross-sectional view illustrating a partial configuration of a semiconductor integrated circuit according to an embodiment of the present invention.

FIG. 3 is a cross-sectional view illustrating a partial configuration of a semiconductor integrated circuit including bonding pads.

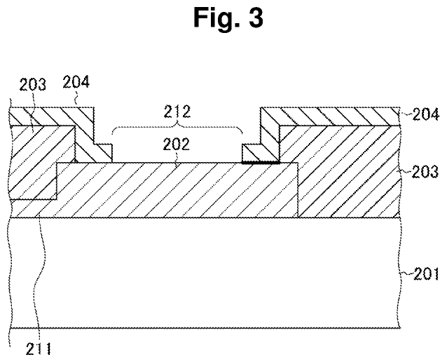

### DESCRIPTION OF EMBODIMENTS

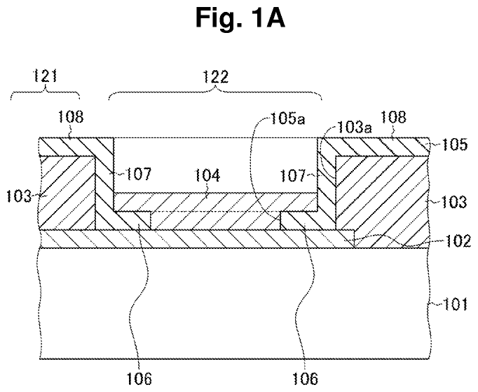

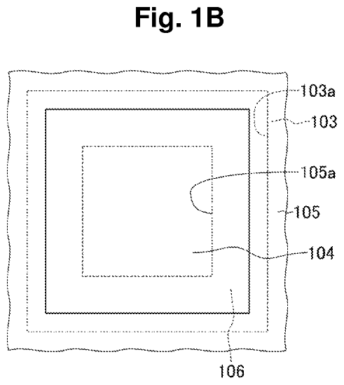

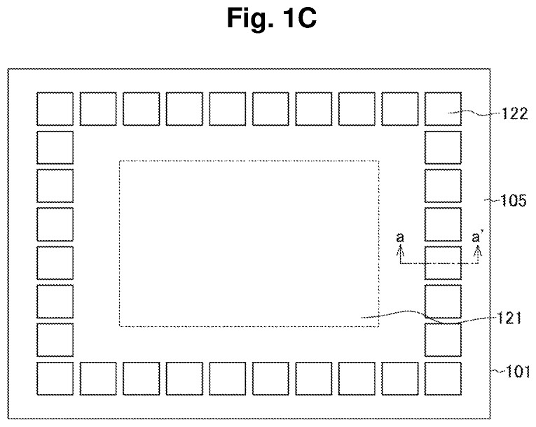

The following is a description of a semiconductor integrated circuit according to an embodiment of the present invention, with reference to FIGS. 1A, 1B, and 1C. FIG. 1A illustrates a cross-section taken along the line aa′ defined in FIG. 1C.

First, this semiconductor integrated circuit includes a substrate 101 formed with a semiconductor, and a circuit element formation region 121 including an element formed with a semiconductor is formed on the substrate 101. The circuit element formation region 121 includes a transistor formed with a semiconductor, a thin-film resistor, an MIM capacitor, a metal wiring line, an interlayer insulating film, and the like, for example. The semiconductor can be a group III-V compound semiconductor, for example. On the substrate 101, pad formation regions 122 are also formed around the circuit element formation region 121.

Further, wiring lines 102, a first protective film 103, bonding pads 104, and a second protective film 105 are formed on the substrate 101.

The wiring lines 102 are drawn from the circuit element formation region 121 onto the substrate 101 in the pad formation regions around the circuit element formation region 121. The wiring lines 102 are formed with a metal such as Au, for example. Also, the wiring lines 102 can be a metal multilayer structure in which the line on the side of the substrate 101 is formed with Au, and the uppermost layer is formed with Ti.

The first protective film 103 is formed with an organic material such as polyimide or benzocyclobutene (BCB), for example, and is formed to cover the circuit element formation region 121. The first protective film 103 also has first openings 103a in the pad formation regions 122.

The bonding pads 104 are formed on the wiring lines 102 inside the first openings 103a with an area smaller than that of the first openings 103a in a planar view. The bonding pads 104 are also connected to the wiring lines 102.

The second protective film 105 is formed on and in contact with the first protective film 103, and is formed to cover the first protective film 103. The second protective film 105 is also formed so that end portions 106 extending toward the centers of the first openings 103a are interposed between the wiring lines 102 and the bonding pads 104 at the edge portions of the bonding pads 104. Further, the second protective film 105 has second openings 105a that are formed on the inner sides of the first openings 103a and have the end portions 106 as the edges. The second protective film 105 also includes the end portions 106, sidewall portions 107 that are formed on the sidewalls of the first openings 103a of the first protective film 103 and continue from the end portions 106, and an upper layer portion 108 formed on the first protective film 103. Further, the second protective film 105 is formed with an inorganic material such as silicon nitride, silicon oxide, or silicon oxynitride, for example.

Also, in this semiconductor integrated circuit, the bonding pads 104 are formed on and in contact with the wiring lines 102 in the regions of the second openings 105a. Further, in the regions where the end portions 106 are interposed between the wiring lines 102 and the bonding pads 104, the wiring lines 102, the second protective film 105, and the bonding pads 104 are stacked in this order from the side of the substrate 101. As described above, since the bonding pads 104 are formed on the end portions 106 of the second protective film 105, peeling of the second protective film 105 can be prevented.

Manufacturing of the semiconductor integrated circuit according to the above-described embodiment is now briefly described. First, the wiring lines 102 are formed on the substrate 101 on which an element formed with a semiconductor is formed. For example, the wiring lines 102 can be formed by an electrode material deposition technique, a photolithography technique, and an etching technique that are well known.

Next, the first protective film 103 is formed on the substrate 101 so as to cover the wiring lines 102. In the first protective film 103, the first openings 103a are formed in the regions including the bonding regions. For example, a photosensitive organic material formed with polyimide, BCB, or the like is applied onto the substrate 101 by a coating method such as spin coating, to form a coating film. Next, patterning is performed on the formed coating film. After that, the coating film subjected to the patterning is cured by heating or the like, and thus, the first protective film 103 can be formed.

Next, the second protective film 105 is formed to cover the first protective film 103. For example, an inorganic insulating material such as silicon nitride or silicon oxynitride is deposited on the entire region of the substrate 101 by a known deposition method such as a plasma CVD method, to form an inorganic insulating film. Patterning is then performed on the inorganic insulating film by a photolithography technique and an etching technique, to form the second openings 105a. Thus, the second protective film 105 can be obtained.

Next, the bonding pads 104 are formed. For example, the bonding pads 104 can be formed by a known electrolytic plating technique or the like.

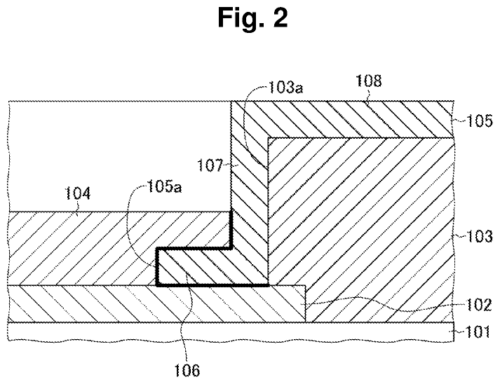

In the semiconductor integrated circuit according to the above-described embodiment, a path between a bonding pad 104 and a sidewall portion 107, a path between the bonding pad 104 and an end portion 106, and a path between the end portion 106 and a wiring line 102 serve as the penetration path of moisture reaching the first protective film 103, as indicated by a bold line in FIG. 2. As described above, according to the embodiment, the area of contact (close contact) between the second protective film 105 formed with an inorganic insulating material and the bonding pad 104 formed with a metal is larger. Further, according to the embodiment, the penetration path of moisture also includes the path between the second protective film 105 and the wiring line 102. In view of these, penetration of moisture reaching the first protective film 103 can be prevented more effectively than in conventional cases.

Also, if a sufficiently large contact area is secured between the lower surface of the bonding pad 104 and the upper surface of the wiring line 102, the opening area of the second opening 105a can be made smaller, the end portion 106 can be made closer to the center of the first opening 103a, and the above-described contact area can be made even larger. Meanwhile, the area of the upper surface of the bonding pad 104 does not change, regardless of the opening area of the second opening 105a. Thus, according to the embodiment described above, penetration of moisture in the bonding pad 104 can be prevented, without a reduction of the bonding region.

Also, in the semiconductor integrated circuit according to the embodiment, a film (a layer) for enhancing the adhesion between the respective components can be formed between the bonding pad 104 and the sidewall portion 107, between the bonding pad 104 and the end portion 106, and between the end portion 106 and the wiring line 102. The film for enhancing adhesion can be formed with Ti or a metal containing Ti, for example. In this manner, the adhesion between the bonding pad 104/the wiring line 102 and the first protective film 103 formed with an organic material can be further enhanced. Thus, penetration of moisture into the bonding pad 104 can be further prevented.

As described above, according to the present invention, end portions of the second protective film formed to cover the first protective film are inserted between the wiring lines and the bonding pads. Thus, it becomes possible to prevent penetration of moisture into the bonding pads by preventing a reduction of the bonding regions. According to the present invention, it is possible to prevent moisture from reaching the circuit element formation region and hindering circuit operations. Also, according to the present invention, there is no need to make the areas of the bonding pads larger, even though sufficiently large bonding region are secured. Thus, it becomes possible to miniaturize and highly densely integrate the semiconductor integrated circuit. As a result, it becomes possible to reduce the cost and size by adopting plastic packaging.

Note that the present invention is not limited to the embodiment described above, and it is obvious that many modifications and combinations can be implemented by a person having ordinary knowledge in the art within the technical idea of the present invention.

### REFERENCE SIGNS LIST

101 substrate
102 wiring line
103 first protective film
103a first opening
104 bonding pad
105 second protective film
105a second opening
106 end portion
107 sidewall portion
108 upper layer portion
121 circuit element formation region
122 pad formation region

1. A semiconductor integrated circuit comprising:
a substrate that is formed with a semiconductor;
a circuit element formation region that is formed on the substrate, and includes an element formed with a semiconductor;
a wiring line that is drawn from the circuit element formation region onto the substrate in a pad formation region around the circuit element formation region;
a first protective film that covers the circuit element formation region, has a first opening formed in the pad formation region, and is formed with an organic material;
a bonding pad that has a smaller area than the first opening in a planar view, is formed on the wiring line on an inner side of the first opening, and is connected to the wiring line; and
a second protective film that is in contact with the first protective film to cover the first protective film, has an end portion extending toward a center of the first opening between the wiring line and the bonding pad at an edge portion of the bonding pad, has a second opening that is formed on the inner side of the first opening and has the end portion as an edge, and is formed with an inorganic material.

2. The semiconductor integrated circuit according to claim 1, wherein,
in a region of the second opening, the bonding pad is formed in contact with the wiring line.

3. The semiconductor integrated circuit according to claim 1, wherein,
in a region in which the end portion extends between the wiring line and the bonding pad, the wiring line, the second protective film, and the bonding pad are stacked in this order from a side of the substrate.

4. The semiconductor integrated circuit according to claim 1, wherein
the second protective film includes the end portion, a sidewall portion that is formed on a sidewall of the first opening of the first protective film and continues from the end portion, and an upper layer portion formed on the first protective film.

5. The semiconductor integrated circuit according to claim 1, further comprising
a film that is formed between the bonding pad and the wiring line, and the first protective film, the film being provided to enhance adhesion to each.

6. The semiconductor integrated circuit according to claim 1, wherein
the wiring line is formed with metal, and
the bonding pad is formed with metal.

7. The semiconductor integrated circuit according to claim 2, wherein,
in a region in which the end portion extends between the wiring line and the bonding pad, the wiring line, the second protective film, and the bonding pad are stacked in this order from a side of the substrate.

8. The semiconductor integrated circuit according to claim 2, wherein
the second protective film includes the end portion, a sidewall portion that is formed on a sidewall of the first opening of the first protective film and continues from the end portion, and an upper layer portion formed on the first protective film.

9. The semiconductor integrated circuit according to claim 3, wherein
the second protective film includes the end portion, a sidewall portion that is formed on a sidewall of the first opening of the first protective film and continues from the end portion, and an upper layer portion formed on the first protective film.

10. The semiconductor integrated circuit according to claim 2, further comprising
a film that is formed between the bonding pad and the wiring line, and the first protective film, the film being provided to enhance adhesion to each.

11. The semiconductor integrated circuit according to claim 3, further comprising
a film that is formed between the bonding pad and the wiring line, and the first protective film, the film being provided to enhance adhesion to each.

12. The semiconductor integrated circuit according to claim 4, further comprising
a film that is formed between the bonding pad and the wiring line, and the first protective film, the film being provided to enhance adhesion to each.

13. The semiconductor integrated circuit according to claim 2, wherein
the wiring line is formed with metal, and
the bonding pad is formed with metal.

14. The semiconductor integrated circuit according to claim 3, wherein
the wiring line is formed with metal, and
the bonding pad is formed with metal.

15. The semiconductor integrated circuit according to claim 4, wherein
the wiring line is formed with metal, and
the bonding pad is formed with metal.

16. The semiconductor integrated circuit according to claim 5, wherein
the wiring line is formed with metal, and
the bonding pad is formed with metal.
